(19) United States
(12) Patent Application Publication
(10) Pub. No.: US 2004/0153947 A1
(43) Pub. Date: Aug. 5, 2004

(54) Method for writing to a defect address memory, and test circuit having a defect address memory

(76) Inventor: Peter Beer, Fontainbleau (FR)

Correspondence Address: GERO G. McCLELLAN, MOSER, PATTERSON & SHERIDAN, L.L.P, Suite 1500, 3040 Post Oak Blvd., Houston, TX, 77056, US

(21) Appl. No.: 10/704,205

(22) Filed: Nov. 6, 2003

(30) Foreign Application Priority Data
Nov. 9, 2002 (DE) 102 52 199.9-53

(51) Int. Cl. G11C 29/00

(52) U.S. Cl. 714/763

(57) ABSTRACT

Method and circuit for writing defect data to a defect address memory in a test system, the defect data indicating whether there is a defect in a memory area of a memory component to be tested, an address in the defect address memory being associated with the memory area, and the address of the defect address memory only being written to when the defect data item indicates a defect.

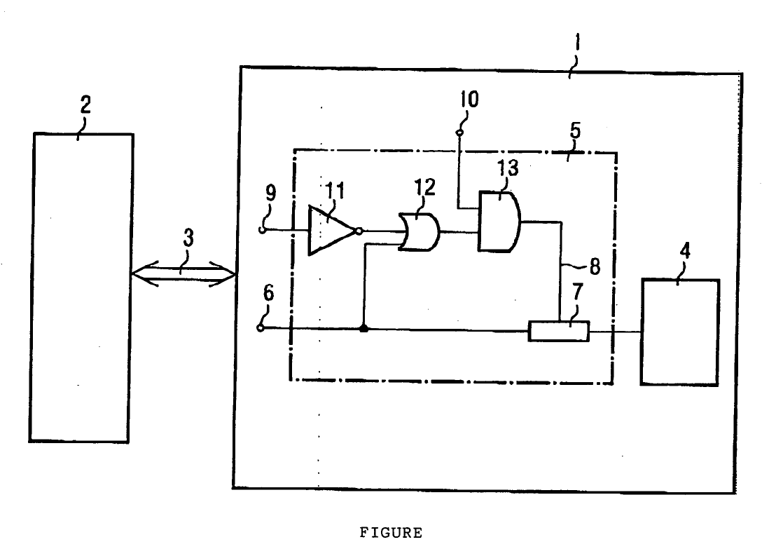

### CROSS-REFERENCE TO RELATED APPLICATIONS

This application claims foreign priority benefits under 35 U.S.C. §119 to co-pending German patent application No.102 52 199.9-53 DE, filed Nov. 9, 2002. This related patent application is herein incorporated by reference in its entirety.

### BACKGROUND OF THE INVENTION

1. Field of the Invention

The invention relates to a method for writing defect data to a defect address memory in a test system. The invention furthermore relates to a test circuit having a defect address memory and a control circuit in order to write defect data to the defect address memory.

2. Description of the Related Art

In order to be tested, integrated memory circuits are connected to a test system. For the purpose of detecting a defect, the test system writes test data to the memory modules. The test data which have been written are subsequently read out again and compared with desired data corresponding to the previously written-in test data. The result of the comparison determines whether the data have been stored correctly or incorrectly in the memory module.

Since memory modules generally provide correction possibilities by means of redundant memory areas, it is necessary to store an item of information regarding the position of the defective memory cell or the area in which the defective memory cell is located. Following completion of the test method, the defective memory areas which have been ascertained, or the addresses thereof, are used to ascertain the optimum repair solution, which indicates the manner in which the memory areas are to be replaced by redundant word lines and bit lines, respectively.

In order to reduce the volume of data received by the test system, the comparison data are compressed in a redundancy-conforming manner, with the result that only the information which is required for calculating the repair solution is transmitted to the tester device. The defect data ascertained in this manner are stored in a “defect address memory” in the tester device.

The defect address memory represents a mapping of the memory module to be tested, the defect address memory, depending on the degree of compression, being smaller than the memory (which is to be tested) of the memory module. A memory position in the defect address memory indicates whether a corresponding memory area in the memory module to be tested is defective or not. In the repair solution, as far as possible all of the defective memory areas are then replaced by functional, redundantly provided memory areas.

If, after test data have been written and the written test data have subsequently been read out and compared with the previously written-in test data, defect data are transmitted to the tester device, said defect data are stored in the defect address memory. Since a plurality of test runs (involving writing and subsequently reading out test data) are carried out, newly occurring defects must be stored in the defect address memory in such a manner that the previously ascertained defect information is not overwritten.

This is particularly important since some of the defects cannot be detected in every test run, with the result that, after a defect has been detected in a memory area, the defective memory cell may even be detected as being free from defects in a subsequent test run. To this end, in the tester device, when new defect data are received, the defect data which have already been stored in the defect address memory are first of all read out, the stored defect data are ORed with the received defect data which are to be written and the result of the ORing is subsequently written back to the defect address memory. This is time-consuming and results in it being necessary to use very fast and thus very expensive memories as defect address memories.

### SUMMARY OF THE INVENTION

It is an object of the present invention to provide a method and a test circuit for a tester device, it being possible to write defect data more rapidly to the defect address memory.

This object is achieved by the method in accordance with claim 1 and also by the test circuit in accordance with claim 3.

The dependent claims specify further advantageous refinements of the invention.

In accordance with a first aspect of the present invention, provision is made of a method for writing defect data to a defect address memory in a test system. The defect data indicate whether there is a defect in a memory area of a memory component to be tested. In this case, an address in the defect address memory is associated with the memory area. The defect data item is only written to the address of the defect address memory when the defect data item indicates a defect.

The method according to the invention provides for defect data which are sent from a memory module to the tester device to be written to a defect address memory. The defect data are written to the defect address memory by a defect data item only being written to the addresses of the defect address memory when the defect data item indicates a defect.

In this manner, that memory area of the memory to be tested which is defective is marked in the defect address memory. In this case, it is not necessary to know whether a defect has previously occurred in the memory area in question or whether a defect in the memory module has already been marked at the address of the defect address memory. The fact that the defect data which indicate that a memory area is free from defects are not stored in the defect address memory prevents a defect data item for a defect-free memory area being written to an address of the defect address memory to which a defect data item for a defective memory area has previously been written. This may be the case when, with various test sequences, a “soft” defect (soft error) occurs in a memory area, it being possible for only some of the test sequences to detect said defect.

The method according to the invention therefore has the advantage that it is not necessary, for the purpose of storing defect data in a defect address memory, to first of all read the defect addresses from the defect address memory, to OR them with the newly received defect data and to subsequently write them back to the defect address memory. In an advantageous manner, it is now possible for those defect data which indicate a defect to be written directly to the defect address memory and to overwrite the corresponding memory addresses of the defect address memory. This makes it possible to use, as the defect address memory, a memory which operates at the same speed as, or at a slower speed than, the memory to be tested instead of having to use a very fast memory, as has been the case hitherto.

In a manner dependent on a mode signal, provision may be made either for defect data to be written to the address of the defect address memory when the defect data item to be written indicates a defect in the memory module to be tested or for further data to be written to the address of the defect address memory. The purpose of the mode signal is to be able to erase the data in the defect address memory again once the test sequence has been carried out, that is to say to write data to the addresses of the defect address memory (it being initially assumed that each memory area of the memory module to be newly tested is free from defects). This would not be possible if the defect address memory were necessarily, that is to say unconditionally, written to.

In accordance with a further aspect of the present invention, provision is made of a test circuit for testing a memory module. The test circuit is designed to receive defect data. The defect data indicate whether there is a defect in a memory area of a memory module to be tested. The test circuit comprises a defect address memory in order to store the defect data at an address of the defect address memory, said address being associated with the memory area. A control circuit is provided for the purpose of writing a defect data item to the address of the defect address memory only when the defect data item indicates a defect.

In this manner, it is possible to provide a test circuit, which makes it possible, when a defect data item is received, to eliminate reading the defect address memory, subsequently ORing the defect information stored in the defect address memory with the received defect data item and then writing to the address of the defect address memory again. Instead it is possible to write the defect data item to the addresses of the defect address memory only when the defect data item indicates that a defect has been detected in the corresponding memory area of the memory module to be tested. The control circuit arranged between the memory module to be tested and the defect address memory thus determines whether a defect data item to be stored in the defect address memory is actually written to the defect address memory or not. This makes it possible to dispense with reading the defect address memory beforehand.

Provision is preferably made for the control circuit to be coupled to a switching device in order to pass the defect data item (to be written) to the defect address memory when the defect data item indicates a defect and the mode signal indicates that the defect address memory is to be operated for the purpose of storing defect data. The mode signal may also indicate that all incoming data are to be stored in the defect address memory. This makes it possible for resetting data to be written to the defect address memory, in particular before a new memory module to be tested is tested, it initially being assumed that all memory areas (to be tested) of the memory module are free from defects.

The control circuit may be designed so as to receive a write signal and, depending on the write signal, to store a defect data item. This makes it possible to deactivate the control circuit when reading the defect address memory.

### BRIEF DESCRIPTION OF THE DRAWINGS

Embodiments of the invention are explained in more detail below with reference to the accompanying Figure which shows a tester device for testing a memory module.

### DETAILED DESCRIPTION OF THE PREFERRED EMBODIMENT

The Figure shows a tester device 1 for testing a memory module 2. The memory module 2 is connected to the tester device 1 via test lines 3. The tester device 1 has a defect address memory 4, which is used to store defect data.

When testing the memory module 2 to be tested, test data are transmitted from the tester device 1 to the memory module and are written there to memory areas of the memory module 2. The test data which have been written are subsequently read out and compared with desired data which are likewise prescribed by the tester device 1. The comparison of test data which have been written with those which have been read out frequently takes place in the memory module 2 (to be tested) itself but may also be carried out in the tester device 1.

When comparing test data which have been written with those which have been read out in the memory module 2 to be tested, the defect data, that is to say the results of the comparisons, may be compressed in a redundancy-conforming manner. Since it is not necessary, for the purpose of ascertaining a repair solution, to know the exact address of a defective memory cell but merely necessary to know the address of the memory area in which the defective memory cell is located, it is sufficient to transmit only the defect address for each memory area to the tester device 1. This makes it possible to considerably reduce the volume of data to be stored.

The defect data which have been ascertained and transmitted in this manner are made available in the tester device 1 for the purpose of being written to the defect address memory 4. The defect address memory 4 has addresses, each of the addresses being associated with a memory area in the memory module 2 to be tested.

A defect data item has a low level when the associated memory area which has been tested does not contain a defective memory cell. It has a high level when there is at least one defective memory cell in the memory area to be tested. Said defect data item must then be stored in the defect address memory 4 in such a manner that it is possible to discern, by means of the address in the defect address memory 4, the associated memory area in the memory module 2 to be tested.

A plurality of test sequences are normally carried out when testing a memory module 2. The test sequences essentially involve writing test data to the memory areas of the memory module, subsequently reading out the data which have been written and then comparing the data which have been written with those which have been read out.

Under certain circumstances, there are types of defect which cannot be detected during every test sequence. These are referred to as soft defects (soft errors) and occur only under certain test conditions. In order that an item of information regarding a defect which has been detected in a particular memory area is not subsequently overwritten by an item of information regarding the detected freedom from defects of the particular memory area, it is not permissible for the received defect data to be written again and again to the defect address memory.

Very fast memories, for example SRAM memories, are normally provided as defect address memories, said fast memories first of all being read when defect data are received, the information which has been read out respectively being ORed with the corresponding defect data associated with the respective address, and the result of the ORing subsequently being written back to the defect address memory 4. The speed of this procedure ultimately determines the test speed at which the memory module 2 to be tested can be tested because the speed at which the defect data can be received is determined thereby.

The invention, then, provides a control circuit 5, which is arranged in the tester device 1 and receives the defect data to be written. The control circuit 5 is connected to the defect address memory 4 in such a manner that, depending on the defect data item which has been received, the defect data item is or is not applied to the defect address memory 4.

The control circuit 5 has a data input 6, to which the defect data transmitted via the test lines 3 may be applied. The data input 6 is connected to the defect address memory 4 via a switching device 7. The switching device 7 is controlled via a switching signal on a control line 8. The switching signal is dependent on a mode signal at a mode input 9 of the control circuit 5 and on a write signal at a write signal input 10 of the control circuit 5.

In a low state, the mode signal indicates that all the data which are present at the data input 6 are written to the defect address memory 4. A high level of the mode signal indicates that only a defect data item which indicates that a defect has been detected in a memory area is applied to the defect address memory 4, depending on the data which are present and depending on a write signal.

To this end, the control circuit 5 has an inverter 11, to the input of which the mode signal is applied. An output of the inverter 11 is connected to one input of an OR gate 12. A second input of the OR gate 12 is connected to the data input 6. An output of the OR gate 12 is connected to a first input of an AND gate 13 and a second input of the AND gate 13 is connected to the write signal input 10. The control signal on the control line 8 is present at the output of the AND gate 13.

If the mode signal indicates, with a high level, that only defect data which indicate a defect are to be written to the defect address memory 4, a low level is present at the first input of the OR gate 12. Since a high level of the defect data item indicates that a defect has occurred, a high level is applied to the second input of the OR gate 12 in the event of a defect, thus resulting in a high level likewise being present at the output of the OR gate 12. In order to write to the defect address memory 4, an active write signal, that is to say a high level of the write signal, must be present at the second input of the AND gate 13. If the write signal indicates that the defect address memory 4 is to be written to, a high level at the first input of the AND gate 13 results in the switching device 7 being turned on. In this manner, the defect data item which is present is applied to the defect address memory 4 and may be written to the corresponding address of the defect address memory 4.

If a defect data item having a low level is present at the data input 6, a low level is likewise present at the output of the OR gate 12 and the AND gate 13 likewise outputs a low level at its output, with the result that the switching device 7 is turned off and the defect data item is not applied to the defect address memory 4. This makes it possible to dispense with ORing the data (which have already been stored in the defect address memory 4) with the received defect data by writing only to the addresses of the defect address memory 4 in whose corresponding memory area of the memory module 2 to be tested a defect has been detected.

The test circuit according to the invention makes it possible to use a defect address memory 4 which does not have to be operated at a higher speed than the memory circuit in the memory module 2 to be tested. The defect address memory 4 provided may preferably be a DRAM memory which, for example, has the same architecture and speed as the memory module to be tested. This makes it possible to dispense with the expensive SRAM memory used hitherto.

The control circuit 5 may be arranged in such a manner that the data input is connected directly to the secondary write amplifiers. The switching device 7 may be in the form of a transmission gate. If the data are already present as differential data at the data input 6, two transmission gates should be provided, each of which is controlled via the control signal on the control line 8.

What is claimed is:

1. A method for selectively writing defect data to an address, the defect data being indicative of whether defects exists in memory areas of a memory component being tested, the method comprising:
providing a defect address memory comprising a plurality of addresses each associated with different memory areas of the memory component being tested;
receiving a defect data for a memory area of the memory component being tested; and
writing the defect data to an address of the defect address memory corresponding to an associated memory area of the memory component being tested only if the defect data indicates a defect in the associated memory area.

2. The method of claim 1, wherein receiving comprises receiving the defect data on a bus connecting the defect address memory to the memory component being tested.

3. The method of claim 1, further comprising:
setting a mode signal to a first state to enable the writing of the defect data to the address; and
setting a mode signal to a second state to enable overwriting the defect data stored at the address.

4. The method of claim 1, wherein writing the defect data is done only if the defect data indicates the defect in the associated memory area and a mode signal is deasserted.

5. A method for selectively writing defect data to an address, the defect data being indicative of whether defects exists in memory areas of a memory component being tested, the method comprising:
providing a defect address memory comprising a plurality of addresses each associated with different memory areas of the memory component being tested;
receiving a defect data for a memory area of the memory component being tested;
writing the defect data to an address of the defect address memory corresponding to an associated memory area of the memory component being tested only if the defect data indicates a defect in the associated memory area and while a mode signal is deasserted; and
resetting the defect address memory while the mode signal is asserted.

6. The method of claim 5, wherein resetting comprises overwriting defect data stored in the defect address memory with other defect data.

7. A method for selectively writing defect data to a defect address memory comprising a plurality of addresses each associated with different memory areas of the memory component being tested, the memory comprising:
providing a mode switchable control circuit coupled to the defect address memory and comprising a first input for defect data and a second input for a mode signal; and
operating the control circuit on the basis of defect data at the first input and a state of the mode signal at the second input so that the defect data is written to an address of the defect address memory corresponding to an associated memory area of the memory component being tested only if the defect data indicates a defect in the associated memory area and the mode signal is deasserted.

8. The method of claim 7, operating the control circuit comprises setting a switch at least on the basis of the state of the mode signal, the switch being coupled to the first input and the defect address memory.

9. The method of claim 7, wherein operating the control circuit further comprises, if the mode signal is asserted, writing the defect data to the defect address memory regardless of whether the defect data indicates a defect in the associated memory area.

10. The method of claim 7, wherein operating the control circuit further comprises, if the mode signal is asserted, overwriting the defect data in the defect address memory to reset the defect address memory.

11. A memory tester circuit, comprising:
an interface to a memory component to be tested;
a defect address memory comprising a plurality of addresses each associated with different memory areas of the memory component to be tested;
a mode switchable control circuit configured to operate in a first mode in which defect data is written to the defect address memory only if the defect data indicates a defect in the associated memory area and further configured to operate in a second mode in which defect data are written to the defect address memory regardless of whether the defect data indicate a defect in memory areas of the memory component to be tested.

12. The memory tester circuit of claim 11, wherein the control circuit operates in the second mode to reset the defect address memory.

13. The memory tester circuit of claim 11, wherein each defect data is received from the memory component.

14. The memory tester circuit of claim 11, wherein the memory tester circuit does not include an ORing circuit for ORing defect data received from the memory component to be tested via the interface and defect data read from the defect address memory.

15. The memory tester circuit of claim 11, wherein the mode switchable control circuit comprises a switch coupled at its output to the defect address memory and having as its inputs (i) the defect data received from the memory component to be tested via the interface and (ii) a switching signal.

16. The memory tester circuit of claim 15, further comprising a plurality of circuit elements configured to assert and deassert the switching signal depending on a mode signal and the defect data received from the memory component to be tested.
